(19) United States
(12) Patent Application Publication
(10) Pub. No.: US 2025/0120150 A1
(43) Pub. Date: Apr. 10, 2025

(54) THIN FILM STRUCTURE AND METHOD OF MANUFACTURING THE THIN FILM STRUCTURE

(71) Applicant: Samsung Electronics Co., Ltd., Suwon-si (KR)

(72) Inventors: Baekwon PARK, Suwon-si (KR); Minseok YOO, Suwon-si (KR); Alum JUNG, Suwon-si (KR); Minsu SEOL, Suwon-si (KR); Hyungjun YOUN, Suwon-si (KR)

(73) Assignee: Samsung Electronics Co., Ltd., Suwon-si (KR)

(21) Appl. No.: 18/674,359

(22) Filed: May 24, 2024

(30) Foreign Application Priority Data
Oct. 4, 2023 (KR) 10-2023-0131938

(51) Int. Cl. H01L 29/18; H01L 21/02; H01L 29/786

(52) U.S. Cl. CPC H10D 62/84; H01L 21/02252; H01L 21/02474; H01L 21/02477; H01L 21/0248; H01L 21/02485; H01L 21/02557; H01L 21/0256; H01L 21/02562; H10D 30/675

(57) ABSTRACT

A thin film structure according to various example embodiments includes a first buffer layer, a transition metal dichalcogenide layer on the first buffer layer, and a second buffer layer on the transition metal dichalcogenide layer, wherein the second buffer layer includes same chalcogen element as a chalcogen element included in the transition metal dichalcogenide layer.

### CROSS-REFERENCE TO RELATED APPLICATION

This application is based on and claims priority under 35 U.S.C. § 119 to Korean Patent Application No. 10-2023-0131938, filed on Oct. 4, 2023, in the Korean Intellectual Property Office, the disclosure of which is incorporated by reference herein in its entirety.

### BACKGROUND

Various example embodiments relate to a thin film structure and/or to a method of manufacturing the thin film structure.

Two-dimensional materials have received attention as new materials for down scaling semiconductor devices. Among them, transition metal dichalcogenide (TMD) has been studied extensively, and has semiconductor properties. In order to commercialize TMD, research on a direct growth method is necessary or desirable. In the related art, a method of synthesizing TMD using a metal organic chemical vapor deposition (MOCVD) method or a chemical vapor transport (CVT) method have been studied. However, the method of the related art has technical limitations that make TMD unsuitable for semiconductor processes due to the use of high temperatures or catalysts.

### SUMMARY

Various example embodiments provide a transition metal dichalcogenide and/or a method of manufacturing the transition metal dichalcogenide.

Additional aspects will be set forth in part in the description which follows and, in part, will be apparent from the description, or may be learned by practice of various example embodiments.

According to some example embodiments, a transition metal dichalcogenide includes a first buffer layer, a transition metal dichalcogenide layer on the first buffer layer, and a second buffer layer on the transition metal dichalcogenide layer. The second buffer layer includes a same chalcogen element as a chalcogen element included in the transition metal dichalcogenide layer.

Alternatively or additionally according to various example embodiments, a method of manufacturing a thin film structure includes forming a first buffer layer, forming a transition metal layer on the first buffer layer, forming a second buffer layer on the transition metal layer, forming a plurality of grain boundaries by crystallizing the first buffer layer and the second buffer layer and forming a transition metal oxide layer from the transition metal layer, and synthesizing a transition metal dichalcogenide layer by replacing oxygen in the transition metal oxide layer with a chalcogen element.

Alternatively or additionally according to various example embodiments, a semiconductor device includes a first gate electrode, a first buffer layer on the first gate electrode, a channel layer on the first buffer layer and including a transition metal dichalcogenide, a source electrode and a drain electrode below the channel layer, a second buffer layer on the channel layer, and a second gate electrode on the second buffer layer. The second buffer layer may include a same chalcogen element as a chalcogen element included in the channel layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram showing a thin film structure according to various example embodiments;

FIG. 2 is a diagram showing a surface of a thin film structure according to various example embodiments;

FIGS. 3A to 3D are diagrams showing a method of manufacturing a thin film structure according to various example embodiments;

FIG. 4 is a diagram showing a semiconductor device according to various example embodiments;

FIG. 5 is a diagram showing a semiconductor device according to various example embodiments;

FIGS. 6A and 6B are diagrams showing a semiconductor device according to various example embodiments; and

FIG. 7 is a cross-sectional view taken along line A-A′ of the semiconductor device of FIG. 6.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a thin film structure and a method of manufacturing the thin film structure according to various embodiments will be described in detail with reference to the attached drawings. In the drawings, like reference numerals refer to like components, and the size of each component in the drawings may be exaggerated for clarity and convenience of explanation. The embodiments of the disclosure are capable of various modifications and may be embodied in many different forms.

Also, when a position of an element is described using an expression “above” or “on”, the position of the element may include not only the element being “immediately in a contact manner” but also being in a non-contact manner”. The singular forms include the plural forms unless the context clearly indicates otherwise. When a portion “includes” an element, another element may be further included, rather than excluding the existence of the other element, unless otherwise described.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Connections or connection members of lines between components shown in the drawings illustrate functional connections and/or physical or circuit connections, and the connections or connection members may be represented by replaceable or additional various functional connections, physical connections, or circuit connections in an actual apparatus.

All examples or example terms are simply used to explain in detail the technical scope various inventive concepts, and thus, the scope not limited by the examples or the example terms as long as it is not defined by the claims.

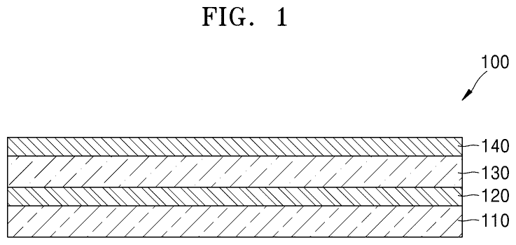

FIG. 1 is a diagram showing a thin film structure 100 according to various example embodiments.

Referring to FIG. 1, the thin film structure 100 includes a substrate 110, a first buffer layer 120 on (or directly on) the substrate 110, a transition metal dichalcogenide (TMD) layer on (or directly on) the first buffer layer 120, and a second buffer layer 140 on (or directly on) the transition metal dichalcogenide layer 130.

The substrate 110 may include at least one of silicon such as single-crystal silicon and/or polysilicon, silicon oxide, aluminum oxide, magnesium oxide, silicon carbide, silicon nitride, glass, quartz, sapphire, graphite, graphene, polyimide copolymer, polyimide, polyethylene naphthalate (PEN), fluoropolymer (FEP), and polyethylene terephthalate (PET), and may or may not be doped with impurities. However, the substrate 110 is not limited thereto.

The first buffer layer 120 may include oxygen atoms. When heat is applied from the outside, oxygen may diffuse from the first buffer layer 120 to adjacent materials and oxidize the adjacent materials. The first buffer layer 120 may include a high-k material, e.g., a material having a dielectric constant greater than that of silicon oxide. The first buffer layer 120 may include at least one of hafnium oxide, aluminum oxide, lanthanum oxide, strontium oxide, and antimony oxide. However, the first buffer layer 120 is not limited thereto. The first buffer layer 120 may include an insulating material including or having a plurality of grain boundaries.

The transition metal dichalcogenide layer 130 may include a transition metal dichalcogenide. The transition metal dichalcogenide is (or corresponds to or incudes) a two-dimensional material having a semiconductor property and is a compound of a transition metal and a chalcogen element. The synthesis of the transition metal dichalcogenide may be performed by providing a chalcogen precursor including a chalcogen element. The transition metal may include, for example, at least one of Mo, W, Nb, V, Ta, Ti, Zr, Hf, Co, Tc, Cu, Te, Ni, Rh, Pd, Ir, Zn, Sn, Pt, Re and Al. The chalcogen element may include, for example, at least one of S, Se, and Te. The transition metal dichalcogenide may include, for example, MoS₂, MoSe₂, MoTe₂, WS₂, WSe₂, Wte₂, ZrS₂, ZrSe₂, HfS₂, HfSe₂, NbSe₂, or ReSe₂. However, the chalcogen element is not limited thereto.

The second buffer layer 140 may include oxygen atoms. The second buffer layer 140 may include a high-k material. The second buffer layer 140 may include at least one of hafnium oxide, aluminum oxide, lanthanum oxide, strontium oxide, and antimony oxide. However, the second buffer layer 140 is not limited thereto. The second buffer layer 140 may include the same or different materials than that included in the first buffer layer 120. Alternatively or additionally, a thickness of the second buffer layer 140 may be the same as, thinner than, or thicker than that of the first buffer layer 120.

The second buffer layer 140 may include an insulating material including or having a plurality of grain boundaries. An average grain size of the second buffer layer 140 may be the same as, greater than, or less than an average grain size of the first buffer layer 120. The plurality of grain boundaries may serve as a passage through which chalcogen elements are supplied. The plurality of grain boundaries of the second buffer layer 140 may act as a passage through which chalcogen elements are supplied, so that the second buffer layer 140 may include chalcogen elements therein. The second buffer layer 140 may include the same chalcogen element as the chalcogen element included in the transition metal dichalcogenide compound layer 130. For example, the second buffer layer 140 may include at least one of S, Se, and Te. However, the second buffer layer 140 is not limited thereto.

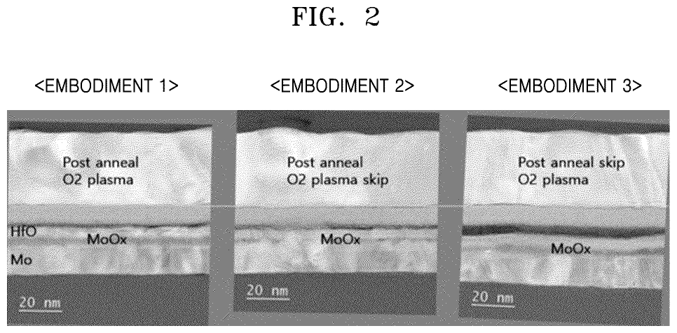

FIG. 2 is a diagram showing a surface of a thin film structure according to various example embodiments.

Referring to FIG. 2, when replacing a transition metal with a transition metal oxide, a profile of the transition metal oxide according to heat treatment and plasma treatment may be seen. The heat treatment is or includes a rapid thermal annealing (RTA) in which heat of about 500° C. is rapidly applied for about 10 minutes. The plasma treatment is an application of oxygen (O₂) plasma. Specifically, the oxygen (O₂) plasma treatment is performed for 30 seconds at an oxygen gas flow rate of 5 sccm under a condition that a power frequency of a power source is 50 kHz and power is 250 W. Pressure is processed at a base pressure 3*E-02 atmospheres and a process pressure 5*E-01 atmospheres.

Embodiment 1 shows a result of performing heat treatment and plasma treatment simultaneously, Embodiment 2 shows a result of performing only heat treatment, e.g., without a subsequent or previous plasma treatment, and Embodiment 3 shows a result of performing only plasma treatment, e.g., without a subsequent or previous heat treatment.

When comparing the profile of molybdenum oxide (MoOx) formed on molybdenum (Mo), it may be seen that the profile of molybdenum oxide (MoOx) is more uniform in Embodiment 1 in which the heat treatment and plasma treatment are simultaneously performed than in Embodiments 2 and 3 in which only the heat treatment or the plasma treatment, respectively, is performed. From this result, it may be seen that a thickness of molybdenum oxide (MoOx) may be uniformly adjusted through heat treatment and/or plasma treatment.

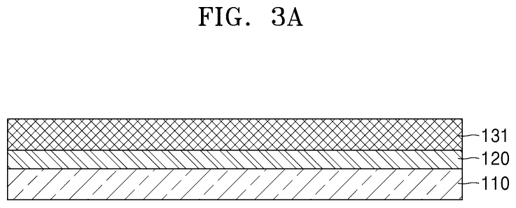

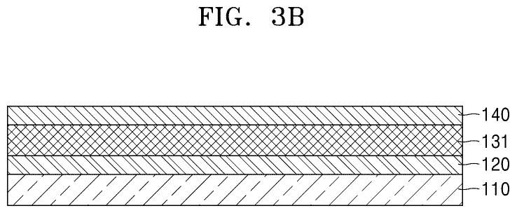

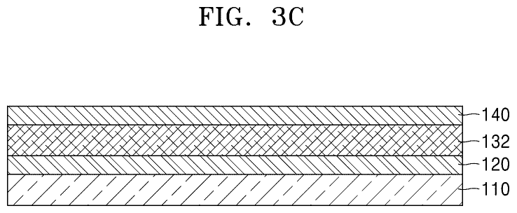

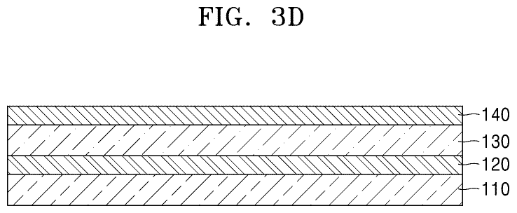

FIGS. 3A to 3D are diagrams showing a method of manufacturing a thin film structure according to various example embodiments.

Referring to FIG. 3A, a first buffer layer 120 is formed on a substrate 110, and a transition metal layer 131 is formed on the first buffer layer 120. The substrate 110 and the first buffer layer 120 may be the same as the substrate 110 and the first buffer layer 120 of FIG. 1. The transition metal layer 131 may include at least one of, for example, Mo, W, Nb, V, Ta, Ti, Zr, Hf, Co, To, Cu, Te, Ni, Rh, Pd, Ir, Zn, Sn, Pt, Re, and Al. Either or both of the transition metal layer 131 and the first buffer layer 120 may be formed with a process such as but not limited to one or more of a chemical vapor deposition (CVD) process such as a low pressure CVD (LPCVD) process and/or a plasma enhanced CVD (PECVD) process, and/or an atomic layer deposition (ALD) process; example embodiments are not limited thereto. In some example embodiments, the transition metal layer 131 and the first buffer layer 120 may be formed with an in-situ deposition process, or, alternatively, with an ex-situ deposition process.

Referring to FIG. 3B, a second buffer layer 140 is formed on the transition metal layer 131. The second buffer layer 140 may be the same as the second buffer layer 140 of FIG. 1. In some example embodiments, the second buffer layer 140 may be formed with one or more of an LPCVD process, a PECVD process, or an ALD process, and may or may not be formed in-situ, e.g., in the same deposition chamber as that of the transition metal layer 131.

Referring to FIG. 3C, the first buffer layer 120 and the second buffer layer 140 are crystallized to form a plurality of grain boundaries, and the transition metal oxide layer 132 is formed from the transition metal layer 131.

The forming of the plurality of grain boundaries by crystallizing the first buffer layer 120 and the second buffer layer 140 and the forming of the transition metal oxide layer 132 from the transition metal layer 131 may use heat treatment. The heat treatment may be or may include a rapid thermal annealing (RTA) and/or a furnace annealing and/or a laser annealing, and in some example embodiments may be performed at a temperature of about 500° C. for about 10 minutes. However, the heat treatment is not limited thereto. The heat treatment may be performed, for example, at a temperature greater than or equal to 300° C. and less than or equal to 1,100° C. for more than or equal to 15 seconds and less than or equal to 30 minutes. When heat treatment is performed, oxygen in the first buffer layer 120 and the second buffer layer 140 diffuses into the transition metal layer 131, thus, the transition metal oxide layer 132 is formed from the transition metal layer 131.

The forming of the plurality of grain boundaries by crystalizing the first buffer layer 120 and the second buffer layer 140 and the forming of the transition metal oxide layer 132 from the transition metal layer 131 may alternatively or additionally use plasma treatment. The forming of the transition metal oxide layer 132 from the transition metal layer 131 may use oxygen (O₂) plasma treatment. For example, the oxygen (O₂) plasma treatment may be performed for 30 seconds at an oxygen flow rate of 5 standard cubic centimeters (sccm) under a condition that the power frequency is 100 KHz and the power is 100 W. Pressure may be processed at a base pressure 1*E-03 and a process pressure 5*E-01. The oxygen (O₂) plasma treatment may be performed under a power condition of, for example, greater than or equal to 20 W and less than or equal to 250 W. For example, the oxygen (O₂) plasma treatment may be performed at a flow rate condition of greater than or equal to 5 sccm and less than or equal to 20 sccm. For example, the oxygen (O₂) plasma treatment may be performed under a base pressure of greater than or equal to 1*E-03 and less than or equal to 1*E-01. The plasma treatment may be performed using mixed gases, such as nitrogen and/or argon in addition to oxygen (O₂) plasma.

The forming of the plurality of grain boundaries by crystallizing the first buffer layer 120 and the second buffer layer 140 and the forming of the transition metal oxide layer 132 from the transition metal layer 131 may use both the heat treatment and plasma treatment. The thickness of the transition metal oxide layer 132 may be uniformly adjusted by using heat treatment and plasma treatment together.

Referring to FIG. 3D, the transition metal dichalcogenide layer 130 is synthesized by replacing oxygen in the transition metal oxide layer 132 with a chalcogen element. The transition metal dichalcogenide layer 130 may include a transition metal dichalcogenide. The synthesizing of a transition metal dichalcogenide by replacing oxygen in the transition metal oxide layer 132 with a chalcogen element may be performed by using a chalcogen precursor including the chalcogen element. The plurality of grain boundaries of the first buffer layer 120 and the second buffer layer 140 may serve as a passage through which the chalcogen precursor is supplied. The second buffer layer 140 may include the same chalcogen element as the chalcogen element included in the transition metal dichalcogenide layer 130.

The transition metal constituting the transition metal dichalcogenide layer 130 may include, for example, at least one of Mo, W, Nb, V, Ta, Ti, Zr, Hf, Co, Tc, Cu, Te, Ni, Rh, Pd, Ir, Zn, Sn, Pt, Re, and Al. The chalcogen element constituting the transition metal dichalcogenide layer 130 may include, for example, at least one of S, Se, and Te. The transition metal dichalcogenide may include, for example, MoS₂, MoSe₂, MoTe₂, WS₂, WSe₂, WTe₂, ZrS₂, ZrSe₂, HfS₂, HfSe₂, NbSe₂, or ReSe₂. However, the transition metal dichalcogenide is not limited thereto.

According to the manufacturing method of according to various example embodiments, because the transition metal layer 131 is replaced by the transition metal dichalcogenide layer 130 between the first buffer layer 120 and the second buffer layer 140 while the transition metal layer 131 is in close contact with the first buffer layer 120 and the second buffer layer 140, the bonding strength between the transition metal dichalcogenide layer 130 and the first and second buffer layer 120 and 140 is improved, or excellent. Alternatively or additionally, a transition metal dichalcogenide may be synthesized by using a low temperature and a non-catalytic direct growth method through a heat treatment or a plasma treatment. This may be beneficial when there is a thermal budget associated with the formation of the semiconductor device 200.

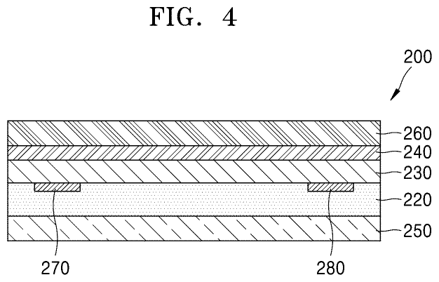

FIG. 4 is a diagram showing a semiconductor device 200 according to various example embodiments.

Referring to FIG. 4, the semiconductor device 200 may include a first gate electrode 250, a first buffer layer 220 on the first gate electrode 250, a channel layer 230 disposed on the first buffer layer 220 and including a transition metal dichalcogenide, a source electrode 270 and a drain electrode 280 disposed below the channel layer 230, a second buffer layer 240 disposed on the channel layer 230, and a second gate electrode 260 disposed on the second buffer layer 240.

The semiconductor device 200 according to various example embodiments may be or may include a field effect transistor (FET) device such as an NMOS and/or PMOS FET device.

The first buffer layer 220 and the second buffer layer 240 may function as an insulating layer. The first buffer layer 220 is disposed between the channel layer 230 and the first gate electrode 250 to electrically disconnect the channel layer 230 and the first gate electrode 250. The second buffer layer 240 is disposed between the channel layer 230 and the second gate electrode 260 to electrically disconnect the channel layer 230 and the second gate electrode 260.

The first buffer layer 220 and the second buffer layer 240 may be provided to surround the channel layer 230. The first buffer layer 220 and the second buffer layer 240 may be the same as the first buffer layer 120 and the second buffer layer 140 of FIG. 1.

The channel layer 230 may serve to form a channel between the source electrode 270 and the drain electrode 280. The channel layer 230 may include a transition metal dichalcogenide. The transition metal may include, for example, at least one of Mo, W, Nb, V, Ta, Ti, Zr, Hf, Co, Tc, Cu, Te, Ni, Rh, Pd, Ir, Zn, Sn, Pt, Re and Al. The chalcogen element may include, for example, at least one of S, Se, and Te. The transition metal dichalcogenide may include, for example, MoS₂, MoSe₂, MoTe₂, WS₂, WSe₂, WTe₂, ZrS₂, ZrSe₂, HfS₂, HfSe₂, NbSe₂, or ReSe₂. However, the transition metal dichalcogenide is not limited thereto.

The source electrode 270 and the drain electrode 280 may be disposed below the channel layer 230 while being spaced apart from each other. The source electrode 270 may be formed or arranged on one side of the channel layer 230 to be electrically connected to the channel layer 230, and the drain electrode 280 may be formed or arranged on the other side of the channel layer 230 to be electrically connected to the channel layer 230. The source electrode 270 and the drain electrode 280 may be disposed on a same surface of the channel layer 230; example embodiments are not limited thereto.

The source electrode 270 and the drain electrode 280 may include an electrically conductive material. The source electrode 270 and the drain electrode 280 may include a metal or a metal compound. The source electrode 270 and the drain electrode 280 may independently or concurrently include, for example, one or more of Au, Ag, Cu, Pt, Pd, Ni, Cr, Co, etc.

The first gate electrode 250 may be referred to as an upper electrode, and the second gate electrode 260 may be referred to as a lower electrode. The first gate electrode 250 and the second gate electrode 260 may independently or concurrently include, for example, one or more of a conductive metal, such as one or more of Au, Ag, or Al, a conductive metal oxide, or a conductive metal nitride.

According to various example embodiments, the channel layer 230 including a TMD may be formed to be surrounded by the first buffer layer 220 and the second buffer layer 240, and thus, a direct growth of the TMD is possible without a transfer process. In addition, a patterning process may be simply progressed, and because a photomask is not applied to a surface of the TMD, performance degradation of the semiconductor device 200 due to traps or impurities may be prevented or reduced in likelihood of and/or impact from occurring.

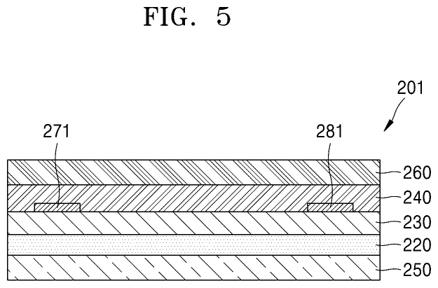

FIG. 5 is a diagram showing a semiconductor device 201 according to various example embodiments.

Referring to FIG. 5, the semiconductor device 201 may include a first gate electrode 250, a first buffer layer 220 disposed on the first gate electrode 250, a channel layer 230 disposed on the first buffer layer 220 and including a transition metal dichalcogenide, a source electrode 271 and a drain electrode 281 disposed on the channel layer 230, a second buffer layer 240 disposed on the channel layer 230, and a second gate electrode 260 disposed on the second buffer layer 240.

The source electrode 271 and the drain electrode 281 may be disposed on the channel layer 230 while being spaced apart from each other. The source electrode 271 may be formed on one side of the channel layer 230 to be electrically connected to the channel layer 230, and the drain electrode 281 may be formed on the other side of the channel layer 230 to be electrically connected to the channel layer 230. The source electrode 271 and the drain electrode 281 may be disposed on a same surface of the channel layer 230.

The semiconductor device 201 may be the same as the semiconductor device 200 of FIG. 4 except that the source electrode 271 and the drain electrode 281 are disposed on the channel layer 230.

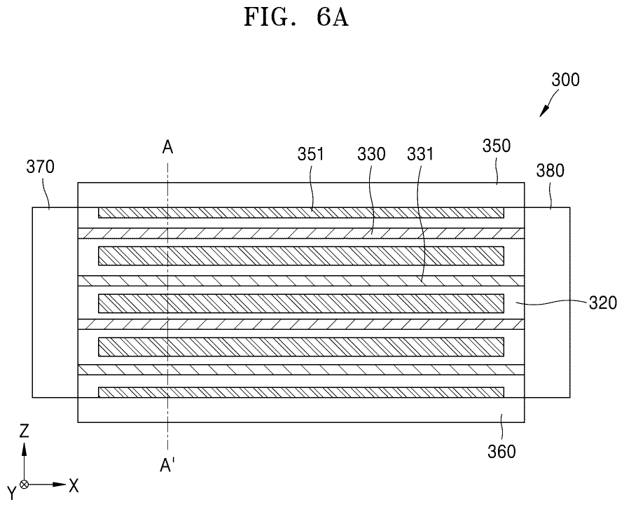

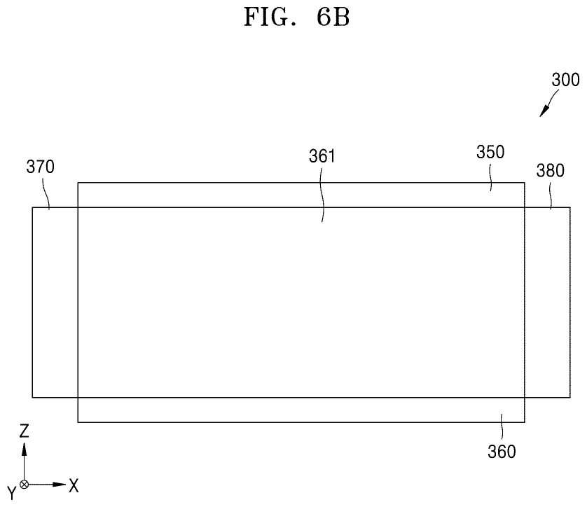

FIGS. 6A and 6B are diagrams showing a semiconductor device 300 according to various example embodiments.

FIG. 6A is a cross-sectional view of the semiconductor device 300 cut from the center of the xz plane, and FIG. 6b is a cross-sectional view of the semiconductor device 300 cut from an edge of the xz plane.

Referring to FIGS. 6A and 6B, the semiconductor device 300 may include a first gate electrode 350 disposed at a top of the semiconductor device 300, a second gate electrode 360 disposed at a bottom of the semiconductor device 300, an insulating layer 320 disposed between the first gate electrode 350 and the second gate electrode 360, a plurality of n-type channel layers 330 and a plurality of p-type channel layers 331 vertically stacked and spaced apart by the insulating layer 320, a plurality of third gate electrodes 351 vertically stacked and spaced apart by the insulating layer 320, a fourth gate electrode 361 connecting the first gate electrode 350, the second gate electrode 360, and the plurality of third gate electrodes 351, a source electrode 370, and a drain electrode 380.

The n-type channel layer 330 may include a transition metal dichalcogenide having an n-type semiconductor property. The n-type channel layer 330 may include, for example, one or more of WS₂, WSe₂, ZrS₂, ZrSe₂, HfS₂, HfSe₂, or NbSe₂.

The p-type channel layer 331 may include a transition metal dichalcogenide having a p-type semiconductor property. The p-type channel layer 331 may include, for example, one or more of MoS₂, MoSe₂, MoTe₂, WSe₂, or WTe₂.

The first insulating layer 320 may include oxygen atoms. The first insulating layer 320 may include a high-k material. The first insulating layer 320 may include at least one of hafnium oxide, aluminum oxide, lanthanum oxide, strontium oxide, and antimony oxide. However, the first insulating layer 320 is not limited thereto.

The first gate electrode 350 may be referred to as an upper gate electrode, and the second gate electrode 360 may be referred to as a lower gate electrode. The first gate electrode 350 and the second gate electrode 360 may include, for example, one or more of a conductive metal, such as at least one of Au, Ag, or Al, a conductive metal oxide, or a conductive metal nitride.

The plurality of third gate electrodes 351 may be disposed on top and bottom of the n-type channel layer 330. The plurality of third gate electrodes 351 may be disposed on top and bottom of the p-type channel layer 331. The third gate electrode 351 may include, for example, a conductive metal, such as Au, Ag, or Al, a conductive metal oxide, or a conductive metal nitride.

The fourth gate electrode 361 may apply a voltage to the semiconductor device 300 by connecting the first gate electrode 350, the second gate electrode 360, and the plurality of third gate electrodes 351. The first gate electrode 350, the second gate electrode 360, the plurality of third gate electrodes 351, and the fourth gate electrode 361 may include the same material. The first gate electrode 350, the second gate electrode 360, the plurality of third gate electrodes 351, and the fourth gate electrode 361 may be connected by one electrode.

The source electrode 370 may be formed on one side of the n-type channel layer 330 to be electrically connected to the n-type channel layer 330, and the drain electrode 380 may be formed on the other side of the n-type channel layer 330 to be electrically connected to the n-type channel layer 330. The source electrode 370 may be formed on one side of the p-type channel layer 331 to be electrically connected to the p-type channel layer 331, and the drain electrode 380 may be formed on the other side of the p-type channel layer 331 to be electrically connected to the p-type channel layer 331.

The source electrode 370 and the drain electrode 380 may include an electrically conductive material. The source electrode 370 and the drain electrode 380 may include a metal and/or a metal compound. The source electrode 370 and the drain electrode 380 may independently or concurrently include, for example, at least one of Au, Ag, Cu, Pt, Pd, Ni, Cr, Co, etc.

The semiconductor device 300 has a structure in which the p-type channel layers 331 and the n-type channel layers 330 are alternately and vertically stacked. As a result, the semiconductor device 300 may implement high integration. Additionally or alternatively, the semiconductor device 300 including the n-type channel layer 330 and the p-type channel layer 331 may be manufactured in one process.

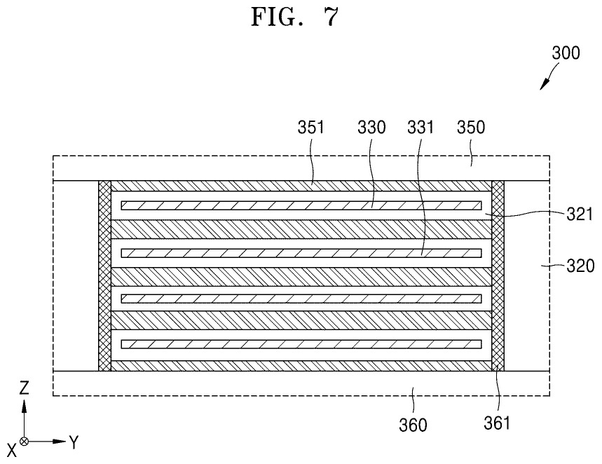

FIG. 7 is a cross-sectional view taken along line A-A′ of the semiconductor device 300 of FIG. 6A.

Referring to FIG. 7, the semiconductor device 300 may further include a second insulating layer 321 in contact with the n-type channel layer 330 and the p-type channel layer 331.

The second insulating layer 321 may include the same material as the first insulating layer 320. The second insulating layer 321 may include oxygen atoms. The second insulating layer 321 may include a high-k material. The second insulating layer 321 may include at least one of hafnium oxide, aluminum oxide, lanthanum oxide, strontium oxide, and antimony oxide. However, the second insulating layer 321 is not limited thereto.

The n-type channel layer 330 may be formed to be surrounded by the second insulating layer 321. The p-type channel layer 331 may be formed to be surrounded by the second insulating layer 321. That is, like the thin film structure formed by the manufacturing method described with reference to FIGS. 3A to 3D, a channel layer including a TMD surrounded by a buffer layer including oxygen atoms may be formed.

The n-type channel layer 330 may be formed to be surrounded by a plurality of third gate electrodes 351. The p-type channel layer 331 may be formed to be surrounded by the plurality of third gate electrodes 351. The plurality of third gate electrodes 351 may be separated from the n-type channel layer 330 and the p-type channel layer 331 with the second insulating layer 321 therebetween. The plurality of third gate electrodes 351 surround the n-type channel layer 330 and the p-type channel layer 331, thus, the semiconductor device 300 may have a gate-all-around structure.

According to various example embodiments, a direct growth of a TMD is possible without a transfer process. For example, a channel layer including a TMD may be directly formed on a gate insulating film. Accordingly, the semiconductor device 300 that is easy or easier to integrate for commercialization may be provided.

According to various example embodiments, a complementary field effect transistor (CFET) device in which a channel layer including a TMD has a length of about 10 nm or less may be manufactured.

The semiconductor devices described above may be used in various electronic devices. For example, the semiconductor devices may be used in one or more of a display driving integrated circuit, a CMOS inverter, a CMOS SRAM device, a CMOS NAND circuit, and/or various other electronic devices.

According to the above manufacturing method, a transition metal dichalcogenide with improved thickness uniformity may be grown directly.

By utilizing the thin film structure, a semiconductor device that is easy or easier to integrate may be provided.

A thin film structure and a method of manufacturing the thin film structure according to various example embodiments may provide a TMD formed by using a non-catalytic direct growth method at a low temperature through heat treatment or plasma treatment. The thin film structure and the method of manufacturing the thin film structure have been described with reference to various example embodiments shown in the drawings. However, it will be understood by those of ordinary skill in the art that various changes in form and details may be made therein without departing from the spirit and scope of the disclosure. Therefore, example embodiments should be considered in descriptive sense only and not for purposes of limitation. The scope of the disclosure is defined not by the detailed description of the disclosure but by the appended claims, and all differences within the scope will be construed as being included in the disclosure.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that embodiments described herein should be considered in a descriptive sense only and not for purposes of limitation. Descriptions of features or aspects within each example embodiment should typically be considered as available for other similar features or aspects in other example embodiments, and example embodiments are not necessarily mutually exclusive with one another. While one or more embodiments have been described with reference to the figures, it will be understood by those of ordinary skill in the art that various changes in form and details may be made therein without departing from the spirit and scope as defined by the following claims.

What is claimed is:

1. A thin film structure comprising:
a first buffer layer;
a transition metal dichalcogenide layer on the first buffer layer; and
a second buffer layer on the transition metal dichalcogenide layer,
wherein the second buffer layer includes a same chalcogen element as a chalcogen element included in the transition metal dichalcogenide layer.

2. The thin film structure of claim 1, wherein the first buffer layer and the second buffer layer each include an insulating material including a plurality of grain boundaries.

3. The thin film structure of claim 1, wherein each of the first buffer layer and the second buffer layer independently includes at least one of hafnium oxide, aluminum oxide, lanthanum oxide, strontium oxide, or antimony oxide.

4. The thin film structure of claim 1, wherein a transition metal included in the transition metal dichalcogenide layer includes at least one of Mo, W, Nb, V, Ta, Ti, Zr, Hf, Co, To, Cu, Te, Ni, Rh, Pd, Ir, Zn, Sn, Pt, Re, and Al.

5. The thin film structure of claim 1, wherein the chalcogen element included in the transition metal dichalcogenide layer includes at least one of S, Se, and Te.

6. A method of manufacturing a thin film structure, the method comprising:
forming a first buffer layer;
forming a transition metal layer on the first buffer layer;
forming a second buffer layer on the transition metal layer;
forming a plurality of grain boundaries by crystallizing the first buffer layer and the second buffer layer, and forming a transition metal oxide layer from the transition metal layer; and
synthesizing a transition metal dichalcogenide layer by replacing oxygen in the transition metal oxide layer with a chalcogen element.

7. The method of claim 6, wherein the forming of a transition metal oxide layer from the transition metal layer uses heat treatment.

8. The method of claim 6, wherein the forming of a transition metal oxide layer from the transition metal layer uses plasma treatment.

9. The method of claim 6, wherein the forming of a transition metal oxide layer from the transition metal layer uses heat treatment and plasma treatment.

10. The method of claim 6, wherein the second buffer layer includes a same chalcogen element as a chalcogen element included in the transition metal dichalcogenide layer.

11. The method of claim 6, wherein the synthesizing of a transition metal dichalcogenide layer by replacing oxygen in the transition metal oxide layer with a chalcogen element uses a chalcogen precursor.

12. The method of claim 6, wherein each of the first buffer layer and the second buffer layer independently includes at least one of hafnium oxide, aluminum oxide, lanthanum oxide, strontium oxide, or antimony oxide.

13. The method of claim 6, wherein a transition metal constituting the transition metal dichalcogenide layer includes at least one of Mo, W, Nb, V, Ta, Ti, Zr, Hf, Co, Tc, Cu, Te, Ni, Rh, Pd, Ir, Zn, Sn, Pt, Re, and Al.

14. The method of claim 6, wherein a chalcogen element included in the transition metal dichalcogenide layer includes at least one of S, Se, and Te.

15. The method of claim 6, wherein the transition metal dichalcogenide layer includes MoS₂, MoSe₂, WS₂, or WSe₂.

16. A semiconductor device comprising:
a first gate electrode;
a first buffer layer on the first gate electrode;
a channel layer on the first buffer layer and including a transition metal dichalcogenide;
a source electrode and a drain electrode below the channel layer;
a second buffer layer on the channel layer; and
a second gate electrode on the second buffer layer,
wherein the second buffer layer includes a same chalcogen element as a chalcogen element included in the channel layer.

17. The semiconductor device of claim 16, wherein the first buffer layer and the second buffer layer each include a plurality of grain boundaries.

18. The semiconductor device of claim 16, wherein each of the first buffer layer and the second buffer layer independently includes at least one of hafnium oxide, aluminum oxide, lanthanum oxide, strontium oxide, or antimony oxide.

19. The semiconductor device of claim 16, wherein a transition metal included in the channel layer includes at least one of Mo, W, Nb, V, Ta, Ti, Zr, Hf, Co, Tc, Cu, Te, Ni, Rh, Pd, Ir, Zn, Sn, Pt, Re, and Al.

20. The semiconductor device of claim 16, wherein a chalcogen element included in the transition metal dichalcogenide includes at least one of S, Se, and Te.
